(19) United States
(12) Patent Application Publication
(10) Pub. No.: US 2013/0009656 A1
(43) Pub. Date: Jan. 10, 2013

(54) TEST PAD STRUCTURE ON WAFER

(76) Inventor: Ping-Chang Wu, Hsinchu County (TW)

(21) Appl. No.: 13/176,721

(22) Filed: Jul. 5, 2011

(51) Int. Cl. G01R 31/00; G01R 1/067

(52) U.S. Cl. 324/755.01

(57) ABSTRACT

A test pad structure on a wafer includes at least a scribe line positioned on a wafer, a pad region defined in the scribe line, and a metal pad positioned in the pad region. An area of the metal pad and an area of the pad region include a ratio, and the ratio is lower than equal to 50%.

### BACKGROUND OF THE INVENTION

1. Field of the Invention

The present invention generally relates to a test pad structure on a wafer, and more particularly, to a test pad structure on a wafer for wafer acceptable test (hereinafter abbreviated as WAT).

2. Description of the Prior Art

In the standard semiconductor process, in order to evaluate the efficiency of each procedure and to confirm performance of the elements after the procedures, a WAT is performed on the wafers. The WAT includes electrical test on the test pad structure disposed around the peripheral regions of the dices. And by analyzing the feedback signal, the stability of the semiconductor processes is confirmed as well as the characteristics and performance of each device of dices.

Prior to the WAT, test keys are formed in the scribe lines around the dice. A device formed in a die is usually for logic computation or for memory, while a similar device is also formed in the scribe line as a part of the test key. The state-of-the-art also provides test pads electrically connected to the test keys. Accordingly, the test keys are electrically connected to an external circuit or probes of a probe card through the test pads to check the quality of the IC process in the WAT. After the WAT, a dicing process is performed to individualize each die on the wafer.

With the progress of the semiconductor fabrication and the miniaturization of the devices, size of the die and width of the scribe lines are consequently shrunk. However, the WAT may fail to convey the performance of the devices and the yield of the processes because the probes do not contact the test pads as expected if the test pads are kept shrinking. In other words, the test pads cannot be shrank as well as the devices and thus the width of the scribe line, which occupies the valuable wafer area, cannot be reduced as expected. Furthermore, it is found that a problem is associated with the test pads: during the dicing process, stress is generated when the dicing saw contacts the test pads, and thus delamination and cracking issue are caused. The delamination and cracking extend along the test pads and propagate toward the dice. More serious, the abovementioned delamination and cracking problem cause reliability concerns as the delamination and the carking damages the dice.

### SUMMARY OF THE INVENTION

According to an aspect of the present invention, a test pad structure on a wafer is provided. The test pad structure includes at least a scribe line formed on a wafer, a pad region defined in the scribe line, and a metal pad positioned in the pad region. An area of the metal pad and an area of the pad region having a ratio, and the ratio is lower than equal to 50%.

According to another aspect of the present invention, a test pad structure on a wafer is further provided. The test pad structure includes at least a scribe line formed on a wafer, a plurality of test keys positioned in the scribe line, and a plurality of metal pads positioned in the scribe line. The metal pads and the test keys are alternately positioned, and the metal pads respectively include at least a pair of opposite sides not parallel with the scribe line.

According to the test pad structure on a wafer provided by the present invention, the metal pad is positioned in the scribe line, particularly in the pad region. The metal pad includes at least a pair of opposite sides not parallel with the scribe line. More important, the area of the metal pad and the area of the pad region have the ratio lower than 40%. Because the area of the metal material in the pad region is decreased, the stress generated in the dicing process is consequently decreased. In other words, the test pad structure on a wafer provided by the present invention solves the delamination and cracking issue in the dicing process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view of a test pad structure on a wafer provided by a first preferred embodiment of the present invention.

FIG. 2 is a top view of a test pad structure on a wafer provided by a second preferred embodiment of the present invention.

FIG. 3 is a top view of a test pad structure on a wafer provided by a third preferred embodiment of the present invention.

FIG. 4 is a top view of a test pad structure on a wafer provided by a fourth preferred embodiment of the present invention.

### DETAILED DESCRIPTION

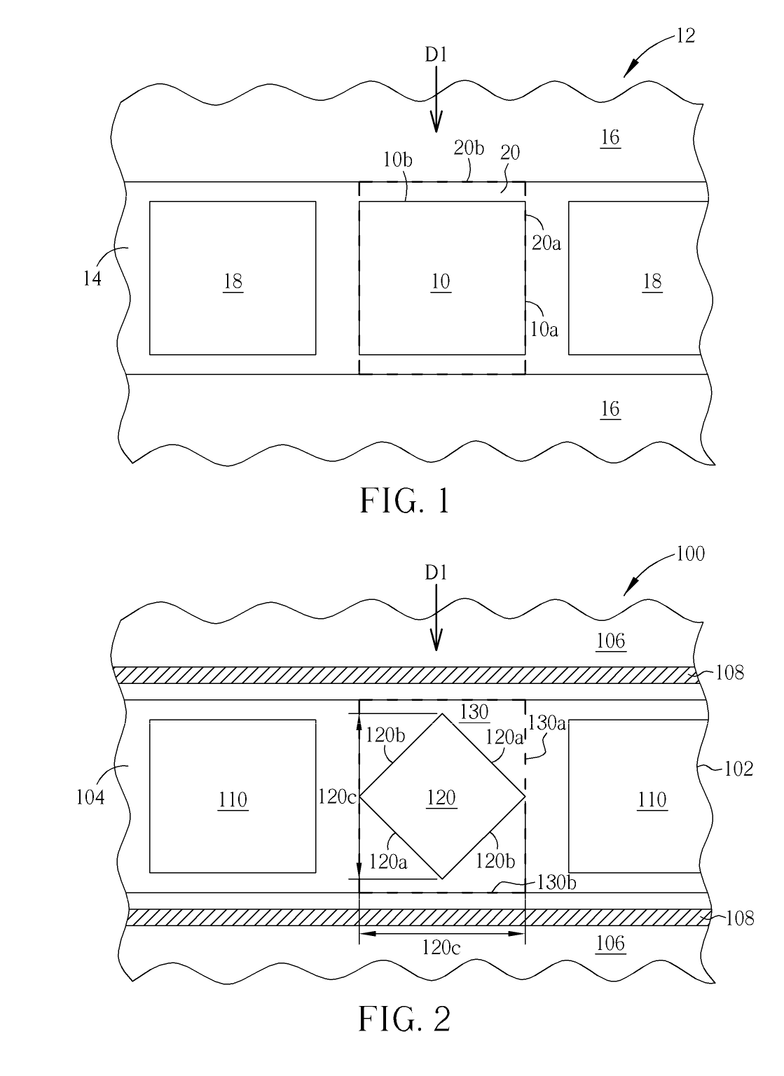

Please refer to FIG. 1, which is a top view of a test pad structure on a wafer provided by a first preferred embodiment of the present invention. It is noteworthy that the first preferred embodiment serves as a comparison. The preferred embodiment first provides a comparison test pad structure 10. The comparison test pad structure 10 is positioned in a scribe line 14 of a wafer 12 while the scribe line 14 is defined in between any two adjacent dices 16 formed on the wafer 12. In the preferred embodiment, a width of the scribe line 14 is exemplarily 62 micrometer (μm). However, those skilled in the art would easily realize that the width of the scribe line 14 can be reduced with the progress of the semiconductor fabrication. Additionally, the comparison test pad structure 10 is electrically connected to a test key 18 positioned in the scribe line 14. As shown in FIG. 1, the comparison test pad structure 10 is a square having first opposite sides 10a and second opposite sides 10b. The first opposite sides 10a are perpendicular to the scribe line 14 while the second opposite sides 10b are parallel with the scribe line 14. Furthermore, D1 shown in FIG. 1 is designated to illustrate an insert direction of probes.

Please still refer to FIG. 1. The comparison test pad structure 10 is positioned in a comparison pad region 20. The comparison pad region 20 is a rectangle having first opposite sides 20a and second opposite sides 20b. The first opposite sides 20a are perpendicular to the scribe line 14 while the second opposite sides 20b are perpendicular to the scribe line 14. The first opposite sides 20a of the comparison pad region 20 include a length, and the length is equal to the width of the scribe line 14. To prevent the die 16 from the cracking extended from the comparison test pad structure 10 during the dicing process, a length of the first opposite sides 10a of the comparison test pad structure 10 provided by the first preferred embodiment is smaller than the width of the scribe line 14, that is, smaller than the length of the first opposite sides 20a of the comparison pad region 20. It is noteworthy that to ensure the comparison test pad structure 10 can be to contacted with the probes (not shown), a length of the second opposite sides 10b of the comparison test pad structure 10 provided by the preferred embodiment is equal to a length of the second opposite sides 20b of the comparison pad region 20. Briefly speaking, to ensure that the comparison test pad structure 10 can be contacted with the probes, a width (the length of the second opposite sides 20b that parallel with the scribe line 14) of the square test structure 10 of the preferred embodiment is maximized without exceeding the scribe line 14. In other word, the first preferred embodiment is to define the comparison pad region 20 according to the width of the scribe line 14 and the width of the square comparison test pad structure 10. Accordingly, an area of the comparison test pad structure 10 and an area of the comparison pad region 20 have a ratio of about 87%. It is found that because the ratio between the comparison test pad structure 10 and the comparison pad region 20 is relatively high, delamination and cracking issue are often resulted during the dicing process in the first preferred embodiment.

Please refer to FIG. 2, which is a top view of a test pad structure on a wafer provided by a second preferred embodiment of the present invention. As shown in FIG. 2, the preferred embodiment provides a test pad structure 100 on a wafer and the test pad structure 100 is positioned in a scribe line 104 of a wafer 102. It is well-known that the scribe line 104 is defined in between any two adjacent dices 106 on the wafer 102 and surrounds the dices 106. Therefore, the dicing saw contacts the scribe line 104 and individualizes the dices 106 along the scribe line 104 in the dicing process. In the preferred embodiment, a width of the scribe line 104 is exemplarily smaller than 62 μm. However, those skilled in the art would easily realize that the width of the scribe line 104 can be reduced with the progress of the semiconductor fabrication. Furthermore, the test pad structure 100 provided by the preferred embodiment includes a pair of die seal rings 108, which is positioned on outsides of the scribe line 104 as shown in FIG. 2. In other words, the die seal rings 108 are positioned between the die 106 and the scribe line 104 for serving as a blocking wall and protecting the die 106 from external stress in the dicing process.

Please still refer to FIG. 2. The test pad structure 100 provided by the second preferred embodiment further includes at least a test key 110 positioned in the scribe line 104. It is noteworthy that the test key 110 is used to check performance of different devices in the die 106, therefore the size and shape of the test key 110 should not be limited to the preferred embodiment. As shown in FIG. 2, the test pad structure 100 provided by the preferred embodiment further includes a metal pad 120 positioned in the scribe line 104 and electrically connected to the test key 110. It should be noted that the metal pads 120 and the test keys 110 are alternately arranged according to the preferred embodiment. However those skilled in the art would easily realize the arrangement of the metal pads 120 and the test keys 110 can be modified if required and thus not limited to this.

The metal pad 120 includes a polygon, such as a rectangle preferably a square as described in the preferred embodiment. The metal pad 120 includes first opposite sides 120a and the second opposite sides 120b having the same lengths. It is noteworthy that the first opposite sides 120a and the second opposite sides 120b of the metal pad 120 provided by the preferred embodiment are not parallel with the scribe line 104 and the die seal ring 108 as shown in FIG. 2. More important, the metal pad 120 of the preferred embodiment includes an internal diameter preferably a maximal internal diameter 120c. According to the preferred embodiment, the maximal internal diameter 120c of the metal pad 120 is the diagonal line of the square metal pad 120. Furthermore, the metal pad 120 of the test pad structure 100 is positioned in a pad region 130, which is a rectangle having first opposite sides 130a and second opposite sides 130b. The first opposite sides 130a of the pad region 130 are perpendicular to the scribe line 104 and the second opposite sides 130b are parallel with the scribe line 104. The first opposite sides 130a of the pad region 130 include a length equal to the width of the scribe line 104. To prevent the die 106 from the cracking extended from the metal pad 120 during the dicing process, a length of the maximal internal diameter 120c of the metal pad 120, that is perpendicular to the scribe line 104 is smaller than the width of the scribe line 104, that is, smaller than the length of the first opposite sides 130a of the pad region 130.

It should be noted that the maximal internal diameter 120c of the metal pad 120 provided by the preferred embodiment can be perpendicular to an insert direction D1 of probes. To ensure that the metal pad 120 can be to contacted with the probes, or to prevent the metal pad 120 from not being contacted with the probes due to transverse movement or misalign of the probes, the length of the maximal internal diameter 120c of the metal pad 120 is maximized without exceeding the width of the scribe line 104. And the maximized length of the maximal internal diameter 120c is also used to define a length of the second opposite sides 130b of the pad region 130. In other words, the preferred embodiment is to define the pad region 130 by the width of the scribe line 104 and the length of the maximal internal diameter 120c of the metal pad 120.

Please refer to FIG. 1 and FIG. 2. For example, the maximal internal diameter 120c of the metal pad 120 provided by the second preferred embodiment is maximized to equal to the width (the length of the second opposite sides 10b parallel with the scribe line 14) of the comparison test pad structure 10 provided by the first preferred embodiment. Therefore, the length of the first opposite sides 130a of the pad region 130 of the second preferred embodiment is equal to the length of the first opposite sides 20a of the comparison pad region 20 of the first preferred embodiment, and the length of the second opposite sides 130b of the pad region 130 of the second preferred embodiment is equal to the length of the second opposite sides 20b of the comparison pad region 20 of the first preferred embodiment. In other words, the size of the pad region 130 of the second preferred embodiment is completely equal to the size of the comparison pad region 20 of the first preferred embodiment. What is different is that the ratio between the area of the metal pad 120 and the area of the pad region 130 is reduced to lower than equal to 50%, such as 40%, according to the second preferred embodiment.

According to the test pad structure on a wafer provided by the second preferred embodiment, the ratio between the area of the metal pad 120 and the area of the pad region 130 is reduced to lower than equal to 40%. It is relatively lower that the ratio described in the first preferred embodiment. Therefore contact areas between the dicing saw and the metal material is reduced during the dicing process, and consequently the stress generated along the metal pad 120 and both the delamination and cracking issues are mitigated. Furthermore, because the maximal internal diameter 120c of the metal pad 120 provided by the preferred embodiment is maximized, it is ensured that the probes is able to contact the metal pad 120 in the WAT and thus the accuracy of the WAT is improved.

In addition, on the premise that the maximal internal diameter 120c of the metal pad 120 is maximized to ensure that the probes is able to contact the metal pad 120, the metal pad 120 can be a rectangle or a rhombus, but not limited to this.

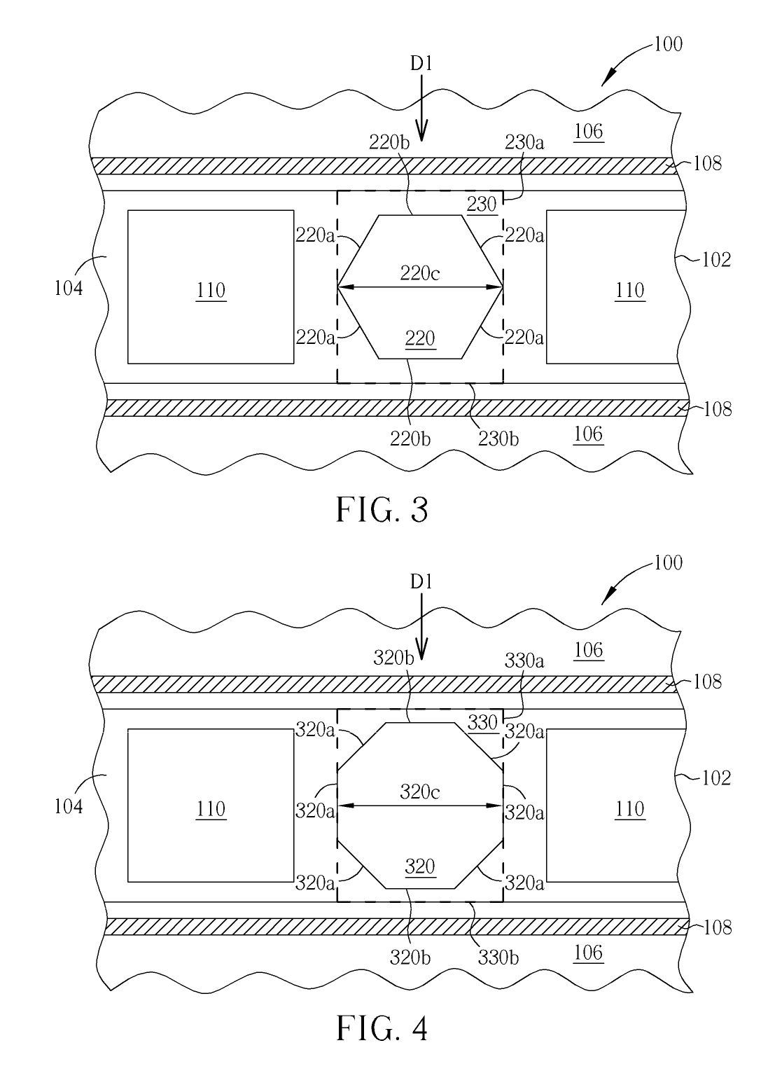

Please refer to FIG. 3 and FIG. 4, which are top views of test pad structures on a wafer respectively provided by a third preferred embodiment and a fourth preferred embodiment of the present invention. It should be noted that elements the same in the third preferred embodiment, the fourth preferred embodiment, and the second preferred embodiment are designated by the same numerals. As shown in FIG. 3 and FIG. 4, the third preferred embodiment and the fourth preferred embodiment respectively provides a test pad structure 200 and 300. The test pad structures 200 and 300 are positioned on a scribe line 104 of a wafer 102, respectively. The scribe line 104 is defined in between any two adjacent dices 106 on the wafer 102 and surrounds the dices 106. Therefore, the dicing saw contacts the scribe line 104 and individualizes the dices 106 along the scribe line 104 in the dicing process. In the third preferred embodiment and the fourth preferred embodiment, a width of the scribe line 104 is smaller than 62 μm. However, those skilled in the art would easily realize that the width of the scribe line 104 can be reduced with the progress of the semiconductor fabrication. Furthermore, the test pad structure 200 provided by the third preferred embodiment and the test pad structure 300 provided by the fourth preferred embodiment respectively include a pair of die seal rings 108, which is positioned on outsides of the scribe line 104. The die seal rings 108 are positioned between the die 106 and the scribe line 104 for serving as a blocking wall and protecting the die 106 from external stress in the dicing process.

Please still refer to FIG. 3 and FIG. 4. The test pad structure 200 provided by the third preferred embodiment and the test pad structure 300 provided by the fourth preferred embodiment respectively include at least a test key 110 positioned in the scribe line 104. It is noteworthy that the test key 110 is used to check performance of different devices in the die 106, therefore the size and shape of the test key 110 should not be limited to the preferred embodiments. As shown in FIG. 3 and FIG. 4, the test pad structure 200 provided by the third preferred embodiment and the test pad structure 300 provided by the fourth preferred embodiment respectively include a metal pad 220 and a metal pad 320 positioned in the scribe line 104 and electrically connected to the test key 110. It is noteworthy that the metal pads 220 and the test keys 110 are arranged alternately in the third preferred embodiment and the metal pads 320 and the test keys 110 are also arranged alternately in the fourth preferred embodiment. However those skilled in the art would easily realize the arrangement of the metal pads 220/320 and the test keys 110 can be modified if required and thus not limited to this.

The metal pad 220 provided by the third preferred embodiment and the metal pad 320 provided by the fourth preferred embodiment respectively include a polygon, such as a regular hexagon in the third preferred embodiment and a regular octagon in the fourth preferred embodiment. As shown in FIG. 3, the metal pad 220 provided by the third preferred embodiment includes at least a pair of first opposite sides 220a not parallel with the scribe line 104 and the die seal rings 108 and at least a pair of second opposite sides 220b parallel with the scribe line 104 and the die seal rings 108. As shown in FIG. 4, the metal pad 320 provided by the fourth preferred embodiment includes at least a pair of first opposite sides 320a not parallel with the scribe line 104 and the die seal rings 108 and at least a pair of second opposite sides 320b parallel with the scribe line 104 and the die seal rings 108. In the second preferred embodiment, it is the vertex corner of the polygon metal pad 120 being proximal to the die seal rings 108 and the scribe line 104. Different from the second preferred embodiment, it is the second opposite side 220b of the metal pad 220 and the second opposite side 320b of the metal pad 320 being proximal to the scribe line 104 and the die seal rings 108 in order to prevent the die 106 from the cracking extended from the metal pad 120 during the dicing process.

The metal pad 220 provided by the third preferred embodiment includes an internal diameter, and preferably a maximal internal diameter 220c. According to the preferred embodiment, the maximal internal diameter 220c of the metal pad 220 is the diagonal line of the regular hexagon metal pad 220. Different from the second preferred embodiment and the third preferred embodiment, the metal pad 320 provided by the fourth preferred embodiment also includes an internal diameter 320c, and the internal diameter 320c is equal to a distance between the opposite sides as shown in FIG. 4. However, the internal diameter 320c also can be the maximal internal diameter, which is the diagonal line of the metal pad 320.

Please still refer to FIG. 3 and FIG. 4. The metal pad 220 of the test pad structure 200 and the metal pad 320 of the test pad structure 300 are position respectively in a pad region 230 and a pad region 330. The pad regions 230 and 330 are rectangle and respectively include first opposite sides 230a, 330a and the second opposite sides 230b, 330b. The first opposite sides 230a, 330a are perpendicular to the scribe line 104 and the second opposite sides 230b, 330b are parallel with the scribe line 104. The first opposite sides 230a, 330a of the pad region 230, 330 include a length and the length is equal to the width of the scribe line 104. As mentioned above, to prevent the die 106 from the cracking extended from the metal pad 220, 320 during the dicing process, the second opposite sides 220b, 320b of the metal pad 220, 320 that are parallel the scribe line 104 and the die seal rings 108 are positioned to be proximal to the die seal rings 108 in the third preferred embodiment and the fourth preferred embodiment. And a distance between the second opposite sides 220b of the metal pad 220 and a distance between the second opposite sides 320b of the metal pad 320 are all smaller than the width of the scribe line 104, that are smaller than the lengths of the first opposite sides 230a, 330a of the pad region 230, 330.

In the third preferred embodiment, the maximal internal diameter 220c of the metal pad 220 is perpendicular to an insert direction D1 of probes. To ensure that the metal pad 220 can be to contacted with the probes, the length of the maximal internal diameter 220c of the metal pad 220 is maximized without exceeding the width of the scribe line 104. And the maximized length 220c is also used to define the length of the second opposite sides 230b of the pad region 230. In other words, the third preferred embodiment is to define the pad region 230 by the width of the scribe line 104 and the length of the maximal internal diameter 220c of the metal pad 220. Different from the second preferred embodiment and the third preferred embodiment, the fourth preferred embodiment is to define the length of the second opposite sides 330b by the internal diameter 320c that is perpendicular to the insert direction D1. Therefore, the fourth preferred embodiment is to define the pad region 330 by the width of the scribe line 104 and the internal diameter 320c of the octagon metal pad 320.

Please refer to FIG. 1, FIG. 3 and FIG. 4 simultaneously. For example, the maximal internal diameter 220c of the metal pad 220 provided by the third preferred embodiment is maximized to equal to the width (the length of the second opposite sides 10b parallel with the scribe line 14) of the comparison test pad structure 10 provided by the first preferred embodiment. And the internal diameter 320c is also maximized to equal to the width of the comparison test pad structure 10. Therefore, the length of the first opposite sides 230a of the pad region 230 of the third preferred embodiment and the length of the first opposite sides 330a of the pad region 330 are equal to the length of the first opposite sides 20a of the comparison pad region 20 of the first preferred embodiment. In the same concept, the length of the second opposite sides 230b of the pad region 230 of the third preferred embodiment and the second opposite sides 330b of the pad region 330 are equal to the length of the second opposite sides 20b of the comparison pad region 20 of the first preferred embodiment. In other words, the size of the pad region 230 of the third preferred embodiment and the size of the pad region 330 of the fourth preferred embodiment are completely equal to the size of the comparison pad region 20 of the first preferred embodiment. However, a ratio between the metal pad 220 and the pad region 230 and a ratio between the metal pad 320 and the pad region 330 are reduced to lower than 72%, compared with the first preferred embodiment.

According to the test pad structures 200 and 300 provided by the third preferred embodiment and the fourth preferred embodiment, the ratio between metal pad 220/320 and the pad region 320/330 are reduced to lower than 72%. It is relatively lower that the ratio described in the first preferred embodiment. Therefore contact areas between the dicing saw and the metal material is reduced during the dicing process, and consequently the stress generated along the metal pad 220/320 and both the delamination and cracking issues are mitigated. Secondly, because the second opposite sides 220b, 320b parallel with the scribe line 140 are arranged to be proximal to die seal rings 108, the die 106 is prevented from the cracking extended from the metal pad 220/320 during the dicing process. Furthermore, because the maximal internal diameter 220c of the metal pad 220 and the internal diameter 320c of the metal pad 320 are maximized, it is ensured that the probes is able to contact the metal pad 220/320 in the WAT and thus the accuracy of the WAT is improved.

It should be noted that the rectangle, hexagon, and octagon metal pad 120/220/320 provided by the all preferred embodiments are exemplarily provided. And the width of the metal pad 120/220/320 that perpendicular to the insert direction D1 of the WAT probes are maintained or maximized while the width of the metal pad 120/220/320 that parallel with the insert direction D1 is reduced. Based on this concept, the metal pad 102/220/320 can include other shapes such as polygons, ellipses, olivary shape, or round shape as long as the ratio between the area of the metal pad and the area of the pad region are reduced.

According to the test pad structure on a wafer provided by the present invention, the metal pad is positioned in the scribe line, particularly in the pad region. The metal pad includes at least a pair of opposite sides not parallel with the scribe line. More important, the area of the metal pad and the area of the pad region have the ratio lower than 72%, even lower than 50%. Because the area of the metal material in the pad region is decreased, the stress generated in the dicing process is consequently decreased. In other words, the test pad structure on a wafer provided by the present invention solves the delamination and cracking issue in the dicing process.

Those skilled in the art will readily observe that numerous modifications and alterations of the device and method may be made while retaining the teachings of the invention.

What is claimed is:

1. A test pad structure on a wafer comprising:
at least a scribe line formed on a wafer;
a pad region defined in the scribe line; and
a metal pad positioned in the pad region, an area of the metal pad and an area of the pad region having a ratio, and the ratio is lower than equal to 50%.

2. The test pad structure on wafer according to claim 1, further comprising a pair of die seal rings respectively positioned on outsides of the scribe line.

3. The test pad structure on wafer according to claim 1, wherein a width of the scribe line is smaller than 62 micrometer (μm).

4. The test pad structure on wafer according to claim 1, wherein the pad region comprises a length and the length is equal to a width of the scribe line.

5. The test pad structure on wafer according to claim 1, wherein the pad region comprises a width and the width is equal to an internal diameter of the metal pad.

6. The test pad structure on wafer according to claim 5, wherein the internal diameter is perpendicular to an insert direction of a probe.

7. The test pad structure on wafer according to claim 6, wherein the internal diameter is a maximal internal diameter of the metal pad, and the maximal internal diameter is a diagonal line of the metal pad.

8. The test pad structure on wafer according to claim 7, wherein the metal pad comprises a polygon.

9. The test pad structure on wafer according to claim 8, wherein the metal pad comprises a square metal pad.

10. The test pad structure on wafer according to claim 6, wherein the internal diameter is a distance between opposite sides of the metal pad.

11. The test pad structure on wafer according to claim 10, wherein the metal pad comprises a polygon.

12. The test pad structure on wafer according to claim 1, further comprising at least a test key positioned in the scribe line, the test key is electrically connected to the metal pad.

13. The test pad structure on wafer according to claim 12, wherein the test key and the metal pad are alternately positioned.

14. A test pad structure on a wafer comprising:
at least a scribe line formed on a wafer;
a plurality of test keys positioned in the scribe line; and
a plurality of metal pads positioned in the scribe line, the metal pads and the test keys being alternately positioned, and the metal pads respectively comprising at least a pair of opposite sides not parallel with the scribe line.

15. The test pad structure on a wafer according to claim 14, further comprising a pair of die seal rings respectively positioned on outsides of the scribe line.

16. The test pad structure on a wafer according to claim 14, wherein a width of the scribe line is lower than 62 μm.

17. The test pad structure on a wafer according to claim 14, wherein the metal pad comprises a polygon.

18. The test pad structure on wafer according to claim 14, wherein the metal pad comprises an internal diameter, and the internal diameter is perpendicular to an insert direction of a probe.

19. The test pad structure on wafer according to claim 18, wherein the internal diameter is a maximal internal diameter of the metal pad, and the maximal internal diameter is a diagonal line of the metal pad.

20. The test pad structure on wafer according to claim 18, wherein the internal diameter is a distance between opposite sides of the metal pad.
